(19) United States
(12) Patent Application Publication
(10) Pub. No.: US 2002/0028546 A1
(43) Pub. Date: Mar. 7, 2002

(54) Method of fabricating deep submicron MOS transistor

(75) Inventors: Hyung Cheol Shin, Yusong-gu (KR); Jong Ho Lee, Iksan-shi (KR); Sang Yeon Han, Yusong-gu (KR); Sung Il Chang, Yusong-gu (KR)

Correspondence Address: MARGER JOHNSON & MCCOLLOM PC, 1030 SW MORRISON STREET, PORTLAND, OR, 97205, US

(73) Assignee: Korea Advanced Institute of Science and Technology, Yusong-gu (KR)

(21) Appl. No.: 09/947,025

(22) Filed: Sep. 4, 2001

(30) Foreign Application Priority Data
Sep. 4, 2000 (KR) 2000-52039

(51) Int. Cl. H01L 21/336

(52) U.S. Cl. 438/197

(57) ABSTRACT

Disclosed is a method of fabricating an MOS transistor. The method comprises the following steps of: forming a gate pattern having a gate insulation film, main gate and a capping layer which are sequentially layered on a p-type semiconductor substrate; forming an isolating insulation film on the whole surface of a resultant structure having the gate pattern; forming a material layer for side gate on the isolating insulation film, the material layer having a work function smaller than those of the semiconductor substrate and the main gate; anisotropically etching the material layer for side gate and the isolating insulation film till the semiconductor substrate and the capping layer are exposed to form an isolating insulation pattern and side gate; respectively forming an n-type source/drain; and forming a conductive film pattern on the resultant structure, the conductive film electrically connecting the source to the adjacent side gate or the drain to the adjacent side gate. According to the invention, even if bias is not applied, an inversion layer is formed in the semiconductor substrate and servers as the source/drain to reduce the short channel effect and mobility of carriers in a channel increases due to low substrate concentration.

### BACKGROUND OF THE INVENTION

1. Field of the Invention

The present invention relates to a method of fabricating an MOS transistor, and more particularly, to a deep submicron MOS transistor.

2. Description of the Related Art

In order to reduce the size of an MOS transistor, the length of a channel thereof should be reduced. It is in expectation that such a channel forming technology will develop more in the next 10 years so that an MOS transistor having the channel length under 50 nm will be fabricated. In order to operate such a deep submicron MOS transistor normally, it is important to minimize the short channel effect, and thus a source/drain junction is required to be formed very shallow.

Conventionally, for the purpose of this, an electrically formed thin inversion layer is used as a source/drain or Phosphorous-doped Silicate Glass (PSG) is used as a side wall, and P is diffused into a silicon substrate through Rapid Thermal Annealing (RTA) to form a shallow junction.

However, such methods are not suitable for mass production and thus application thereof is almost impossible. In other words, those methods provide a structure in which relatively high voltage should be applied, or in which only channel length is reduced without reducing the size of a device itself while reliable device features can be hardly obtained in process. Accordingly, it is required to solve those drawbacks.

### SUMMARY OF THE INVENTION

Accordingly, the present invention has been proposed to solve the foregoing problems of the prior art and it is a technical object of the invention to provide a method for fabricating an MOS transistor which forms a thin inversion layer in a silicon substrate using a difference in work functions, even if bias is not applied, and allows the thin inversion layer to serve as a source/drain, thereby reducing the short channel effect while increasing mobility of carriers in a channel.

According to the first embodiment of the invention to solve the object, it is provided a method of fabricating an MOS transistor, the method comprising the following steps of: forming a gate pattern having a gate insulation film, a main gate and a capping layer which are sequentially layered on a p-type semiconductor substrate; forming an isolating insulation film on the whole surface of a resultant structure having the gate pattern; forming a material layer for side gate on the isolating insulation film, the material layer having a work function smaller than those of the semiconductor substrate and the main gate; anisotropically etching the material layer for side gate and the isolating insulation film till the semiconductor substrate and the capping layer are exposed to form an isolating insulation pattern and side gate; respectively forming an n-type source/drain; and forming a conductive film pattern on the resultant structure, the conductive film electrically connecting the source to the adjacent side gate or the drain to the adjacent side gate.

According to the second embodiment of the invention to solve the object, it is provided a method of fabricating an MOS transistor in the same fashion as the first embodiment by replacing the p-type semiconductor substrate with an SOI substrate having a p-type semiconductor layer at the top thereof.

In the methods of the invention, the main gate is made of one selected from a group including p⁺-type polysilicon, p⁺-type SiGe and a mid-gap material, the material layer for side gate is made of n⁺-type polysilicon, and the isolating insulation film is one selected from a group including an oxide film, a nitride film, an oxynitride and a Ta₂O₅ film.

The methods of the invention further comprise the step of forming a p-type halo ion implantation area which contains more impurities implanted thereto than the p-type semiconductor or the p-type semiconductor layer of the SOI substrate before or after the step of forming the source/drain.

According to the third embodiment of the invention to solve the object, it is provided a method of fabricating an MOS transistor, the method comprising the following steps of: forming a gate pattern having a gate insulation film, a main gate and a capping layer which are sequentially layered on an n-type semiconductor substrate; forming an isolating insulation film on the whole surface of a resultant structure having the gate pattern; forming a material layer for side gate on the isolating insulation film, the material layer having a work function larger than those of the semiconductor substrate and the main gate; anisotropically etching the material layer for side gate and the isolating insulation film till the semiconductor substrate and the capping layer are exposed to form an isolating insulation pattern and side gate; respectively forming p-type source/drain; and forming a conductive film pattern on the resultant structure, the conductive film electrically connecting the source to the adjacent side gate or the drain to the adjacent side gate.

According to the fourth embodiment of the invention to solve the object, it is provided a method of fabricating an MOS transistor in the same fashion as the third embodiment by replacing the n-type semiconductor substrate with an SOI substrate having an n-type semiconductor layer at the top thereof.

In the methods of the invention, the main gate is made of n⁺-type polysilicon, the material layer for side gate is made of p-type polysilicon, and the isolating insulation film is one selected from a group including an oxide film, a nitride film, an oxynitride and a Ta₂0₅ film.

The methods of the invention further comprise the step of forming an n-type halo ion implantation area which contains more impurities implanted thereto than the n-type semiconductor or the n-type semiconductor layer of the SOI substrate before or after the step of forming the source/drain.

### BRIEF DESCRIPTION OF THE DRAWINGS

In the appended drawings:

FIGS. 1A to IF are sectional views for illustrating a fabricating method of an MOS transistor according to the first embodiment of the invention;

FIG. 2A shows an energy band diagram between a main gate and a substrate, FIG. 2B shows an energy band diagram between a side gate and the substrate shown in FIG. 1B; and

FIG. 3 shows energy band diagrams between a main gate and a substrate (a) and between a side gate and the substrate (b) according to the second embodiment of the invention.

### DETAILED DESCRIPTION OF THE PREFERRED EMBODIMENT

Hereinafter, detailed description will be made about preferred embodiments of the invention in reference to the accompanied drawings:

Embodiment 1

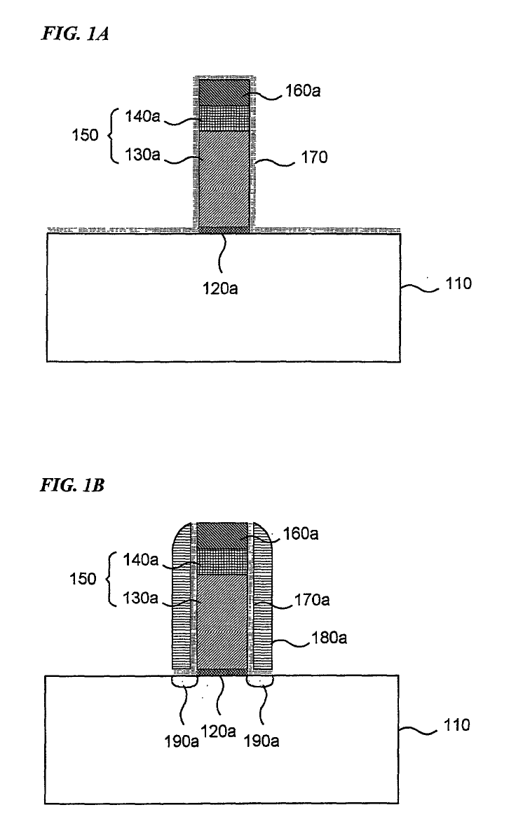

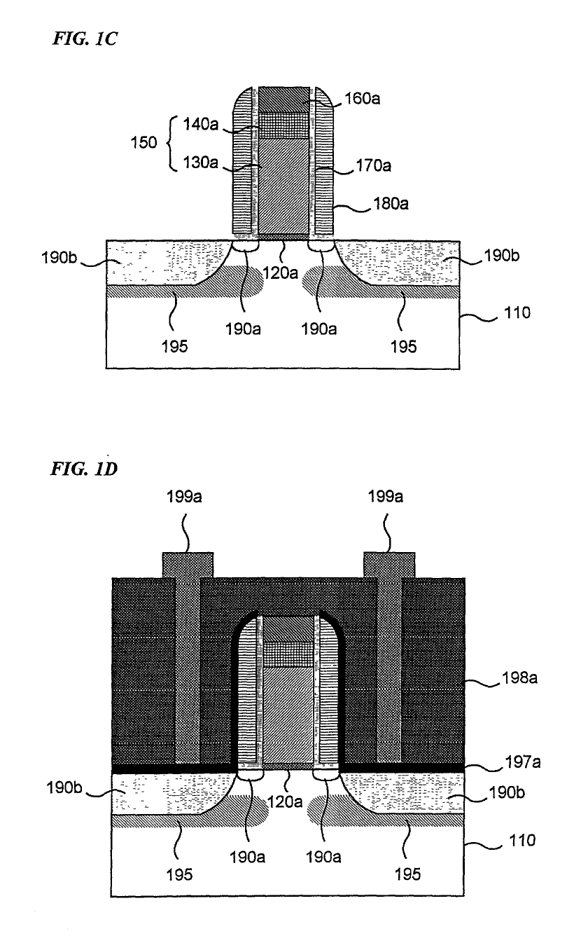

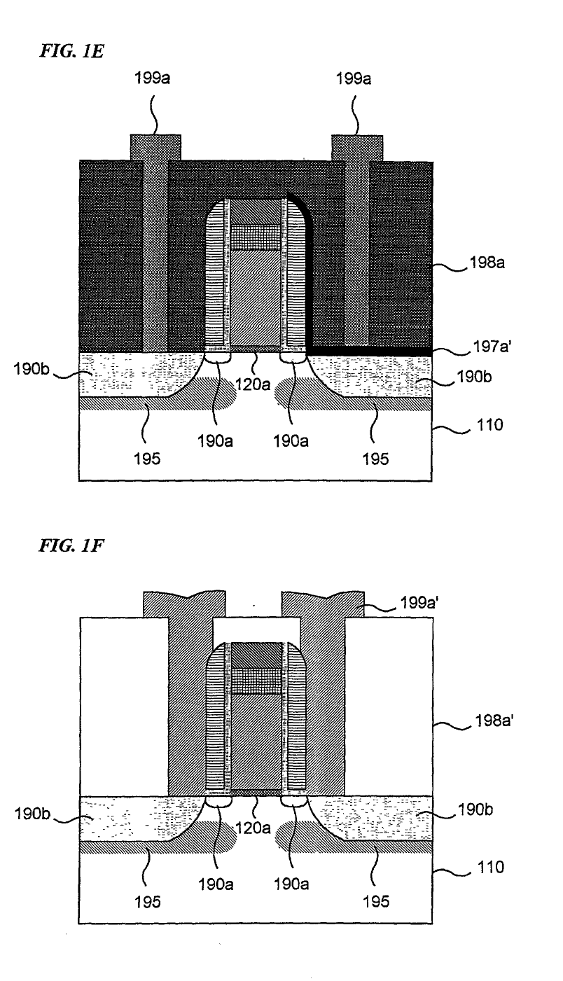

FIGS. 1A to IF are sectional views for illustrating a fabricating method of an MOS transistor according to the first embodiment of the invention.

FIGS. 1A and 1B illustrate steps for forming a main gate 150, a capping layer 160a, an isolating insulation film pattern 170a and a side gate 180a.

First, a gate insulation film 120a, the main gate 150 and the capping layer 160a are sequentially layered on a p-type silicon substrate 110 in a conventional method to form a gate pattern. In this case, the capping layer 160a is composed of a silicon nitride or a silicon oxide, and the main gate 150 has a polycide structure in which a material layer 130a, for example, a p⁺-type polysilicon layer, having a work function larger than that of the substrate 110 and a silicide layer 140a are layered in sequence.

Next, on the whole surface of the resultant structure having the gate pattern is formed an isolating insulation film 170. Examples of the isolating insulation film 170 may include an oxide film, a nitride film, an oxynitride and a Ta₂O₅ film. Preferably, the isolating insulation film 170 is made of a material with a higher dielectric constant so as to assist the formation of an inversion layer 190a which will be described hereinafter.

Then, after a material layer for side gate is formed on the isolating insulation film 170, the material layer for side gate and the isolating insulation film 170 are anisotropically etched to form an isolating insulation layer pattern 170a and side gate 180a shaped as a spacer. In this case, the material layer for side gate is formed of n⁺-type polysilicon having a work function smaller than that of the substrate 110.

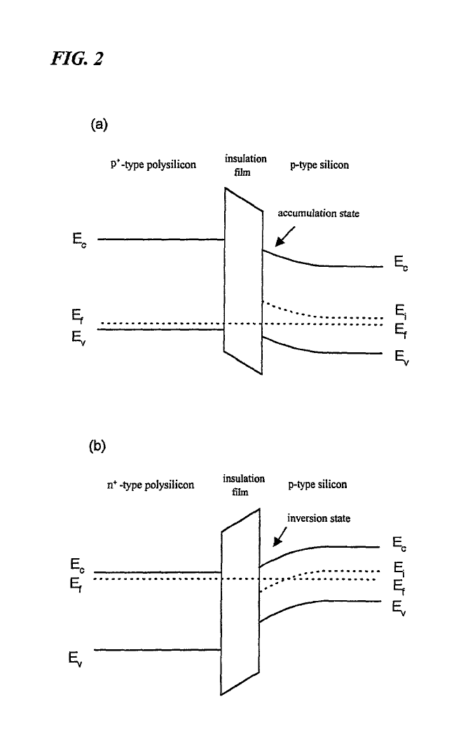

FIG. 2A illustrates the energy band diagram between the main gate 150 and the substrate 110, and FIG. 2B illustrates the energy band diagram between the side gate 180a and the substrate 110.

Referring to FIG. 2A, since the P⁻-type substrate 110 has a work function of 5.03 to 5.13 eV and the p⁺-type polysilicon has a work function of about 5.29 eV, in the equilibrium, the energy band of the substrate 110 is bent upward and the surface of the substrate 110 is in a state of accumulation.

Referring to FIG. 2B, since the p⁻-type substrate 110 has a work function of 5.03 to 5.13 eV and the n⁺-type polysilicon used as the side gate 180a has a work function of about 4.17 eV, in the equilibrium, the energy band of the substrate 110 is bent downward and the surface of the substrate is in a state of inversion. Therefore, as shown in FIG. 1B, the n-type inversion layer 190a is formed under the side gate 180a while no inversion layer is formed under the main gate 150.

FIGS. 1C and 1D illustrate steps for forming halo ion implantation area 195, a source/drain 190b, a conductive layer pattern 197a and metal lines 199a.

First of all, in order to prevent punch-through, halo ion is implanted to form the halo ion implantation area. Then, the n-type source/drain 190b is formed through ion implantation. In this case, the sequence of forming the halo ion implantation area 195 and the source/drain 190b can be interchanged. Alternatively, retrograde wells may be formed instead of the halo ion implantation area 195 to obtain the same effect.

Second, the resultant structure is deposited on the whole surface with refractory metal such as Ti, Co or W followed by heat treatment to transform only a portion of refractory metal contacting the substrate 110 and the side gate 180a into silicide and remove the remaining portion of the refractory metal which is not transformed into silicide, thereby forming the self-aligned conductive film pattern 197a for electrically connecting the side gate at the source side to the source and the side gate at the drain side to the drain, respectively.

Third, the resultant structure with the conductive film pattern 197a is deposited on the whole surface with an interlayer insulation film followed by anisotropic etching to form an interlayer insulation pattern 198a having contact holes for partially exposing the conductive film pattern 197a. Then, the metal lines 199a are formed filling the contact holes for electrically connecting to the conductive film pattern 197a. The main gate 150 and the side gate 180a may be made of other metallic materials instead of polysilicon as well as satisfying the concept of the device of the invention. However, when the side gate 180a is made of the other materials rather than polysilicon, the conductive film pattern 197a cannot be formed using the foregoing self-aligned silicide or salicide process, whereas patterning steps are required to form the conductive film pattern 197a. In other words, the conductive layer is necessarily deposited on the whole surface of the resultant structure having the source/drain 190b and then patterned to form the conductive pattern 197a of the foregoing configuration.

It is not required to electrically connect the source to the adjacent side gate and the drain to the adjacent side gate as shown in FIG. 1D, whereas one of the source and the drain may be connected to the adjacent one of the side gates using a conductive film pattern 197″ as shown in FIG. 1E.

Also, instead of the salicide or patterning process described in reference to FIG. 1D each of the source/drain can be electrically connected to the side gate as shown in FIG. 1F, which will be described in detail as follows: An interlayer insulation film is formed on the whole surface of the resultant structure of FIG. 1C and then anisotropically etched to form an interlayer insulation film pattern 198a′ having contact holes for exposing all of the side gate 180a and the source/drain 190b. Then, through the contact holes of the interlayer insulation film pattern 198a″ are formed conductive landing pads 199a′ connected to the source/drain 190b.

In an NMOS transistor obtained according to the invention, the difference between threshold voltages of the main gate 150 and the side gate 180a is proportional to the difference between work functions thereof. For example, when the main gate 150 is made of p⁺-type polysilicon having a work function of 5.29 eV and the side gate 180a is made of n⁺-type polysilicon having a work function of 4.17 eV, the difference of the threshold voltage is about 1.12 V.

Therefore, when the device is fabricated to have the threshold voltage of the main gate of 0.8 V, the threshold voltage of the side gate is −0.42 V so that the n-type inversion layer 190a is formed in the substrate 110 under the side gate 180a even if the side gate is not applied with bias. When the conductive film pattern 197a or 197a′ or the landing pads 199a′ are applied with voltage, such n-type inversion layer 190a actually serves as the source/drain, resultantly reducing the short channel effect. Also, the same effect can be obtained when the side gate at the source side is maintained floating and only the side gate at the drain side is electrically connected to the drain, as shown in FIG. 1E. In this case, the effect of reducing the channel length is less than in FIG. 1D, however, when the main gate 150 is applied with voltage, the side gate at the source side is applied with voltage proportional to that of the main gate 150 caused by the capacitive coupling effect so that inversion is higher under the side gate at the source side to increase current flowing through the channel.

While only the p⁻-type silicon substrate 110 has been described in the first embodiment, an SOI substrate having a p⁻-type semiconductor layer at the top thereof can be replaced for the p⁻-type silicon substrate 110.

Embodiment 2

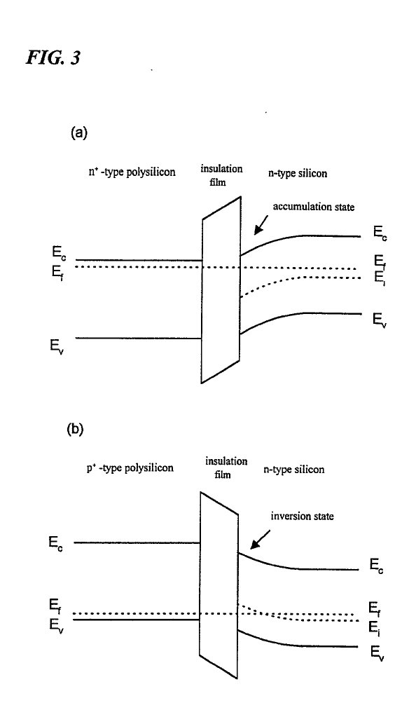

While the NMOS transistor has been exemplified so far, it will be the same in a POSE transistor except that the main gate utilizes a material with a work function smaller than that of a substrate and side gate utilizes a material with a work function smaller than that of the substrate. For example, when an n-type silicon substrate is used, the main gate is made of n⁺-type polysilicon as shown in FIG. 3A, and the side gate is made of p⁺-type polysilicon as shown in FIG. 3B. Further, an SOI substrate having an n-type semiconductor layer at the top can be replaced for the n-type silicon substrate.

According to the method of fabricating the MOS transistor of the invention as described hereinbefore, since the substrate 110 has a low doping concentration, a thin inversion layer 190a is formed on the surface of the substrate 110 even if the side gate 180a is not applied with voltage. Since the inversion layer 190a is electrically connected to the source/drain 190b by the conductive layer pattern 197a, the inversion layer 190a also servers as a source/drain thereby reducing the short channel effect. According to the invention, a deep submicron MOS transistor can be fabricated with a channel length of or under 0.1 μm without greatly departing from a conventional process.

Further, according to the invention, the channel has a low doping concentration to reduce the scattering effect so that mobility of carriers may be improved while fluctuation of threshold voltage caused by ununiform distribution of doped impurities can be minimized.

Although the preferred embodiments of the present invention have been disclosed for illustrative purposes, those skilled in the art will appreciate that the present invention is not restricted to the foregoing embodiments, but various modifications, additions and substitutions thereof can be made without departing from the scope and spirit of the invention as recited in the accompanying claims.

What is claimed is:

1. A method of fabricating an MOS transistor, said method comprising the following steps of:
forming a gate pattern having a gate insulation film, a main gate and a capping layer which are sequentially layered on a p-type semiconductor substrate;
forming an isolating insulation film on the whole surface of a resultant structure having the gate pattern;
forming a material layer for side gate on the isolating insulation film, the material layer having a work function smaller than those of the semiconductor substrate and the main gate;
anisotropically etching the material layer for side gate and the isolating insulation film till the semiconductor substrate and the capping layer are exposed to form an isolating insulation pattern and side gate;
respectively forming an n-type source/drain; and
forming a conductive film pattern on the resultant structure, the conductive film electrically connecting the source to the adjacent side gate or the drain to the adjacent side gate.

2. A method of fabricating an MOS transistor according to claim 1, wherein the main gate is made of one selected from a group including p⁺-type polysilicon, p+-type SiGe and a mid-gap material.

3. A method of fabricating an MOS transistor according to claim 1, wherein the material layer for side gate is made of n⁺-type polysilicon.

4. A method of fabricating an MOS transistor according to claim 1, wherein the isolating insulation film is one selected from a group including an oxide film, a nitride film, an oxynitride and a Ta₂O₅ film.

5. A method of fabricating an MOS transistor according to claim 1, further comprising the step of forming a p-type halo ion implantation area which contains more impurities implanted thereto than the p-type semiconductor before or after said step of forming the source/drain.

6. A method of fabricating an MOS transistor, said method comprising the following steps of:
forming a gate pattern having a gate insulation film, a main gate and a capping layer which are sequentially layered on an SOI substrate having a p-type semiconductor layer at the top thereof;
forming an isolating insulation film on the whole surface of a resultant structure having the gate pattern;
forming a material layer for side gate on the isolating insulation film, the material layer having a work function smaller than those of the p-type semiconductor substrate and the main gate;
anisotropically etching the material layer for side gate and the isolating insulation film till the p-type semiconductor substrate and the capping layer are exposed to form an isolating insulation pattern and side gate;
respectively forming an n-type source/drain; and
forming a conductive film pattern on the resultant structure, the conductive film electrically connecting the source to the adjacent side gate or the drain to the adjacent side gate.

7. A method of fabricating an MOS transistor according to claim 6, wherein the main gate is made of one selected from a group including p⁺-type polysilicon, p⁺-type SiGe and a mid-gap material.

8. A method of fabricating an MOS transistor according to claim 6, wherein the material layer for side gate is made of n⁺-type polysilicon.

9. A method of fabricating an MOS transistor according to claim 6, wherein the isolating insulation film is one selected from a group including an oxide film, a nitride film, an oxynitride and a Ta₂O₅ film.

10. A method of fabricating an MOS transistor according to claim 7, further comprising the step of forming a p-type halo ion implantation area which contains more impurities implanted thereto than the p-type semiconductor layer of the SOI substrate before or after said step of forming the source/drain.

11. A method of fabricating an MOS transistor, said method comprising the following steps of:
forming a gate pattern having a gate insulation film, a main gate and a capping layer which are sequentially layered on an n-type semiconductor substrate;
forming an isolating insulation film on the whole surface of a resultant structure having the gate pattern;
forming a material layer for side gate on the isolating insulation film, the material layer having a work function larger than those of the semiconductor substrate and the main gate;
anisotropically etching the material layer for side gate and the isolating insulation film till the semiconductor substrate and the capping layer are exposed to form an isolating insulation pattern and side gate;
respectively forming a p-type source/drain; and
forming a conductive film pattern on the resultant structure, the conductive film electrically connecting the source to the adjacent side gate or the drain to the adjacent side gate.

12. A method of fabricating an MOS transistor according to claim 11, wherein the main gate is made of n⁺-type polysilicon.

13. A method of fabricating an MOS transistor according to claim 11, wherein the material layer for side gate is made of p-type polysilicon.

14. A method of fabricating an MOS transistor according to claim 11, wherein the isolating insulation film is one selected from a group including an oxide film, a nitride film, an oxynitride and a Ta₂O₅ film.

15. A method of fabricating an MOS transistor according to claim 11, further comprising the step of forming an n-type halo ion implantation area which contains more impurities implanted thereto than the n-type semiconductor before or after said step of forming the source/drain.

16. A method of fabricating an MOS transistor, said method comprising the following steps of:
forming a gate pattern having a gate insulation film, a main gate and a capping layer which are sequentially layered on an SOI substrate having an n-type semiconductor layer at the top thereof;
forming an isolating insulation film on the whole surface of a resultant structure having the gate pattern;
forming a material layer for side gate on the isolating insulation film, the material layer having a work function larger than those of the n-type semiconductor substrate and the main gate;
anisotropically etching the material layer for side gate and the isolating insulation film till the n-type semiconductor substrate and the capping layer are exposed to form an isolating insulation pattern and side gate;
respectively forming a p-type source/drain; and
forming a conductive film pattern on the resultant structure, the conductive film electrically connecting the source to the adjacent side gate or the drain to the adjacent side gate.

17. A method of fabricating an MOS transistor according to claim 16, wherein the main gate is made of n⁺-type polysilicon.

18. A method of fabricating an MOS transistor according to claim 16, wherein the material layer for side gate is made of p-type polysilicon.

19. A method of fabricating an MOS transistor according to claim 16, wherein the isolating insulation film is one selected from a group including an oxide film, a nitride film, an oxynitride and a Ta₂O₅ film.

20. A method of fabricating an MOS transistor according to claim 16, further comprising the step of forming an n-type halo ion implantation area which contains more impurities implanted thereto than the n-type semiconductor layer of the SOI substrate before or after said step of forming the source/drain.
